(19) United States
(12) Patent Application Publication
(10) Pub. No.: US 2026/0077394 A1
(43) Pub. Date: Mar. 19, 2026

(54) CLEANING SHEET, TRANSFER MEMBER PROVIDED WITH CLEANING FUNCTION, AND METHOD OF PRODUCING CLEANING SHEET

(71) Applicant: NITTO DENKO CORPORATION, Osaka (JP)

(72) Inventor: Yuichi FUKAMICHI, Ibaraki-shi (JP)

(21) Appl. No.: 19/324,403

(22) Filed: Sep. 10, 2025

(30) Foreign Application Priority Data
Sep. 13, 2024 (JP) 2024-159379

(51) Int. Cl. B08B 7/00; C09D 179/08; H01L 21/687

(52) U.S. Cl. CPC B08B 7/0028; C09D 179/08; H10P 72/7616

(57) ABSTRACT

Provided is a cleaning sheet excellent in cleanliness, foreign particle-removing performance, and transfer performance. The cleaning sheet includes a cleaning layer. The cleaning layer contains a polyimide-based resin. The cleaning layer has an amount of a metal transferred to a silicon wafer of 1×10¹¹ atoms/cm² or less, which is measured by a total reflection X-ray fluorescence analysis method.

### CROSS-REFERENCE TO RELATED APPLICATION(S)

This application claims priority to Japanese Patent Application No. 2024-159379 filed on Sep. 13, 2024, which is herein incorporated by references.

### BACKGROUND OF THE INVENTION

### Field of the Invention

The present invention relates to a cleaning sheet, a transfer member provided with a cleaning function, and a method of producing a cleaning sheet.

### Description of the Related Art

In various kinds of substrate processing apparatus that are liable to be damaged by foreign particles, such as production apparatus and inspection apparatus for a semiconductor, a flat panel display, a printed board, and the like, a transfer device (typically a chuck table or the like) and a substrate are transferred while being brought into physical contact with each other. In this case, when foreign particles adhere to the transfer device, the subsequent substrates are contaminated one after another, and hence it is required to stop the apparatus periodically so as to clean the apparatus. As a result, there arise problems in that the operation rate of the processing apparatus decreases, and that a great amount of time and labor are required for cleaning the apparatus.

In addition, foreign particles derived from a human may be mixed in at the time of the cleaning.

In order to solve such problems as described above, a method of removing foreign particles adhering to a transfer device by transferring a plate-shaped member into a substrate processing apparatus (see Japanese Patent Application Laid-open No. Hei 11-87458) has been proposed. According to the method, it is not required to stop a substrate processing apparatus so as to clean the apparatus, and hence the problem of the decrease in operation rate of the processing apparatus is solved. According to the method, however, it has been impossible to sufficiently remove the foreign particles each adhering to the transfer device.

In addition, a method of removing foreign particles each adhering to a transfer device by transferring a substrate with an adherent material adhering thereto as a cleaning member into a substrate processing apparatus (see Japanese Patent Application Laid-open No. Hei 10-154686) has been proposed. This method is excellent in foreign particle-removing performance as compared to the method described in Japanese Patent Application Laid-open No. Hei 11-87458. In the method described in Japanese Patent Application Laid-open No. Hei 10-154686, however, there may arise a problem in that the adherent material and the transfer device are bonded to each other so strongly in a contact portion therebetween that the material and the device are not separated from each other. As a result, there may arise a problem in that the substrate with the adherent material adhering thereto cannot be securely transferred, a problem in that the transfer device is damaged, and a problem in that the transfer device is contaminated. Meanwhile, when an adhesive strength between the adherent material and the transfer device becomes excessively small, there may arise a problem in that the foreign particle-removing performance of the cleaning member reduces, and hence a sufficient cleaning effect is not obtained.

Further, there is also a problem in that the cleaning member itself is a cause of the contamination in the production process depending on the configuration of the cleaning member or the method of producing the cleaning member. In particular, metal impurities are a serious cause of defects in substrate (wafer) processing.

### SUMMARY OF THE INVENTION

An object of the present invention is to provide a cleaning sheet excellent in cleanliness, foreign particle-removing performance, and transfer performance.

According to at least one embodiment of the present invention, there is provided a cleaning sheet, including a cleaning layer, wherein the cleaning layer contains a polyimide-based resin, and wherein the cleaning layer has an amount of a metal transferred to a silicon wafer of 1×10¹¹ atoms/cm² or less, which is measured by a total reflection X-ray fluorescence analysis method.

In the cleaning sheet according to the above-mentioned item 1, the cleaning layer may have an amount of Ca transferred to the silicon wafer of 1×10¹¹ atoms/cm² or less, which is measured by the total reflection X-ray fluorescence analysis method.

In the cleaning sheet according to the above-mentioned item 1 or 2, a metal content in the cleaning layer may be 10 ppm or less.

In the cleaning sheet according to any one of the above-mentioned items 1 to 3, a Na content and a Ca content in the cleaning layer may each be 10 ppm or less.

In the cleaning sheet according to any one of the above-mentioned items 1 to 4, the cleaning layer may have an indentation modulus of elasticity at 25° C. of from 0.1 GPa to 2 GPa.

The cleaning sheet according to any one of the above-mentioned items 1 to 5 may further include a support arranged adjacent to the cleaning layer.

According to at least one embodiment of the present invention, there is provided a transfer member provided with a cleaning function, including: the cleaning sheet of any one of the above-mentioned items 1 to 6; and a transfer member.

According to at least one embodiment of the present invention, there is provided a method of producing a cleaning sheet, including applying a composition for forming a cleaning layer to a support, wherein a Na concentration and a Ca concentration in the composition for forming a cleaning layer are each 10 ppm or less.

The method of producing a cleaning sheet according to the above-mentioned item 8 may further include measuring one of the Na concentration or the Ca concentration in the composition for forming a cleaning layer.

According to one embodiment of the present invention, the cleaning sheet excellent in cleanliness, foreign particle-removing performance, and transfer performance can be provided.

### BRIEF DESCRIPTION OF THE DRAWINGS

FIG. 1 is a schematic cross-sectional view for illustrating a cleaning sheet according to at least one embodiment of the present invention.

FIG. 2 is a schematic cross-sectional view for illustrating a cleaning sheet according to at least one embodiment of the present invention.

FIG. 3 is a schematic cross-sectional view for illustrating a cleaning sheet according to at least one embodiment of the present invention.

FIG. 4 is a schematic cross-sectional view for illustrating a transfer member provided with a cleaning function according to at least one embodiment of the present invention.

### DESCRIPTION OF THE EMBODIMENTS

### A. Cleaning Sheet

### A-1. Overview

A cleaning sheet according to at least one embodiment of the present invention includes a cleaning layer. The cleaning sheet according to at least one embodiment of the present invention may include only the cleaning layer, or may include any other layer.

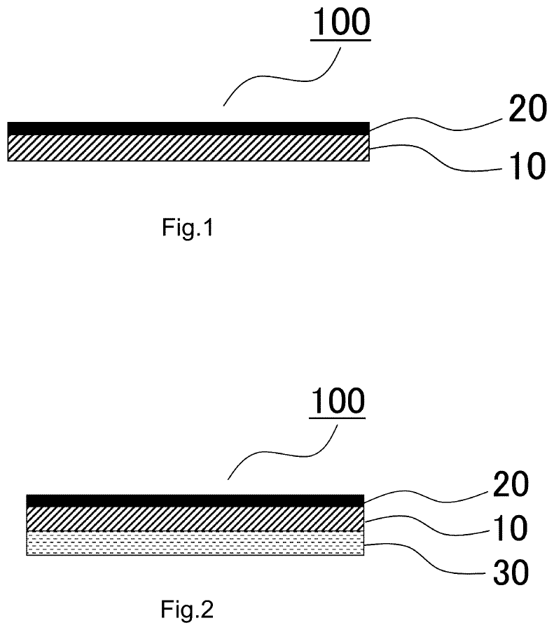

FIG. 1 is a schematic cross-sectional view for illustrating a cleaning sheet according to at least one embodiment of the present invention. In FIG. 1, a cleaning sheet 100 includes a cleaning layer 10 and a protective film 20 arranged on at least one surface of the cleaning layer 10. The protective film 20 may be arranged for the purpose of, for example, protecting the cleaning layer 10, and may be omitted in accordance with purposes. That is, the cleaning sheet according to at least one embodiment of the present invention may include only the cleaning layer 10.

FIG. 2 is a schematic cross-sectional view for illustrating a cleaning sheet according to at least one embodiment of the present invention. In FIG. 2, the cleaning sheet 100 includes the protective film 20, the cleaning layer 10, and a pressure-sensitive adhesive layer 30 in the stated order. The protective film 20 may be arranged for the purpose of, for example, protecting the cleaning layer 10, and may be omitted in accordance with purposes.

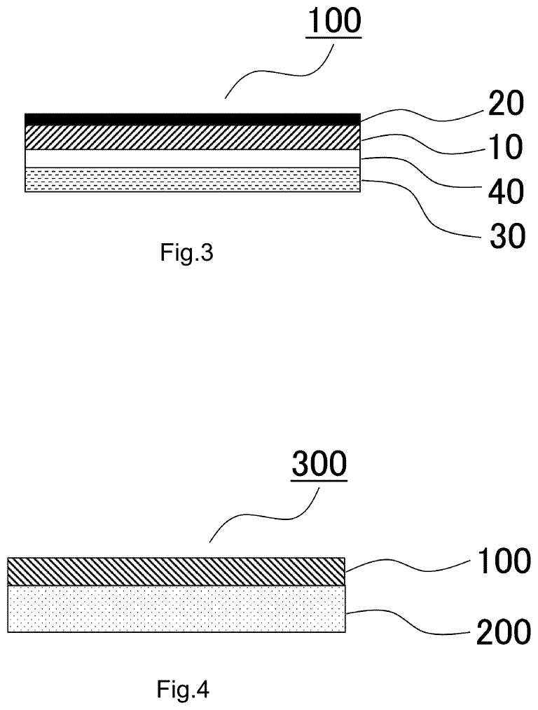

The cleaning sheet according to at least one embodiment of the present invention may further include a support arranged adjacent to the cleaning layer. In at least one embodiment of the present invention, the support is arranged in contact with the cleaning layer. The support may be a support for transfer such as a dummy wafer. FIG. 3 is a schematic cross-sectional view for illustrating a cleaning sheet according to at least one embodiment of the present invention. In FIG. 3, the cleaning sheet 100 includes the protective film 20, the cleaning layer 10, a support 40, and the pressure-sensitive adhesive layer 30 in the stated order. The protective film 20 may be arranged for the purpose of, for example, protecting the cleaning layer 10, and may be omitted in accordance with purposes. In addition, the pressure-sensitive adhesive layer 30 may be omitted.

### A-2. Cleaning Layer

The cleaning layer has an amount of a metal transferred to a silicon wafer of 1×10¹¹ atoms/cm² or less, which is measured by a total reflection X-ray fluorescence analysis method. When the cleaning layer has such configuration, a cleaning sheet excellent in cleanliness that can prevent contamination derived from the cleaning layer can be obtained. The cleaning sheet exhibits excellent performance as a cleaning member of a predetermined apparatus by virtue of a combination of its own cleanliness and foreign particle-removing performance. The cleaning layer as described above may be formed by using a clean composition (varnish) for forming a cleaning layer. In at least one embodiment of the present invention, the cleanliness of the composition (varnish) for forming a cleaning layer may be evaluated by Na and Ca contents in the varnish. In addition, the cleaning layer as described above may be formed by a production process without manual intervention. Typically, the detection limit of the amount of the metal transferred to the silicon wafer measured by the total reflection X-ray fluorescence analysis method is about 1×10¹¹ atoms/cm². In at least one embodiment of the present invention, the lower limit of the amount of the metal transferred to the silicon wafer is 0 atoms/cm². Examples of the metal include Ti, Cr, Mn, Ni, Fe, Co, Cu, and Zn. For any of those metals, the amount of the metal transferred is preferably 1×10¹¹ atoms/cm² or less. A measurement method for the amount of the metal transferred is as described later.

The cleaning layer preferably has an amount of Ca transferred to the silicon wafer of 1×10¹¹ atoms/cm² or less, which is measured by the total reflection X-ray fluorescence analysis method. When the cleaning layer has such configuration, a cleaning sheet excellent in cleanliness that can prevent contamination derived from the cleaning layer can be obtained. Typically, the detection limit of the amount of Ca transferred to the silicon wafer measured by the total reflection X-ray fluorescence analysis method is about 1×10¹¹ atoms/cm². In at least one embodiment of the present invention, the lower limit of the amount of the metal transferred to the silicon wafer is 0 atoms/cm². The amount of Ca transferred may be measured by the same method as in the amount of the metal transferred except that Ca is used as the measurement object.

The metal content in the cleaning layer is preferably 10 ppm or less, more preferably 8 ppm or less, still more preferably 6 ppm or less. When the metal content falls within such ranges, a cleaning sheet excellent in cleanliness that can prevent contamination derived from the cleaning layer can be obtained. Examples of the metal include Ti, Cr, Mn, Ni, Fe, Co, Cu, and Zn. For any of those metals, the metal content in the cleaning layer preferably falls within the above-mentioned ranges. The metal content in the cleaning layer is preferably as low as possible, and the lower limit thereof is, for example, 1 ppm (preferably 0 ppm). The metal content, and a Na content and a Ca content to be described later in the cleaning layer may be measured by ICP-MS as described later.

The Na content in the cleaning layer is preferably 10 ppm or less, more preferably 8 ppm or less, still more preferably 6 ppm or less. When the Na content falls within such ranges, a cleaning sheet excellent in cleanliness that can prevent contamination derived from the cleaning layer can be obtained. The Na content in the cleaning layer is preferably low, and the lower limit thereof is, for example, 1 ppm (preferably 0 ppm).

The Ca content in the cleaning layer is preferably 10 ppm or less, more preferably 8 ppm or less, still more preferably 6 ppm or less. When the Ca content falls within such ranges, a cleaning sheet excellent in cleanliness that can prevent contamination derived from the cleaning layer can be obtained. The Ca content in the cleaning layer is preferably low, and the lower limit thereof is, for example, 1 ppm (preferably 0 ppm).

In at least one embodiment of the present invention, the Na content and the Ca content in the cleaning layer are each preferably 10 ppm or less, more preferably 8 ppm or less, still more preferably 6 ppm or less.

The thickness of the cleaning layer is, for example, from 1 μm to 100 μm. The thickness of the cleaning layer may be from 1 μm to 50 μm, from 1 μm to 30 μm, or from 1 μm to 20 μm.

In at least one embodiment of the present invention, the cleaning layer is substantially free of an adhesive ability. Specifically, the cleaning layer has a 180° peeling adhesion A of preferably less than 0.20 N/10 mm, more preferably from 0.01 N/10 mm to 0.10 N/10 mm, which is defined by JIS-Z-0237 with respect to the mirror surface of a silicon wafer. When the 180° peeling adhesion A of the cleaning layer with respect to the mirror surface of the silicon wafer, which is defined by JIS-Z-0237, falls within such ranges, the cleaning layer is substantially free of an adhesive ability, and hence the pressure-sensitive adhesive property of a contact portion between the cleaning layer and, for example, a transfer device in a substrate processing apparatus can be reduced. As a result, a substrate can be securely transferred, and the transfer device can be hardly damaged.

The cleaning layer has a 180° peeling adhesion B with respect to the mirror surface of a dummy wafer of preferably 2 N/10 mm or more, more preferably 3 N/10 mm or more, still more preferably 3.5 N/10 mm or more, particularly preferably 5 N/10 mm or more, most preferably 7 N/10 mm or more. When the 180° peeling adhesion B falls within the above-mentioned ranges, for example, adhesiveness between the cleaning layer and a transfer member such as the dummy wafer becomes higher, and hence the cleaning layer hardly peels from the transfer member such as the dummy wafer during cleaning. The 180° peeling adhesion B with respect to the mirror surface of the dummy wafer is preferably as high as possible, but the upper limit thereof is, for example, 20 N/10 mm (preferably 30 N/10 mm, more preferably 50 N/20 mm). The 180° peeling adhesion B is measured by, for example, forming the cleaning layer on the mirror surface of the silicon wafer serving as the dummy wafer. The 180° peeling adhesion B is measured for a sample piece having a width of 10 mm and a length of 100 mm under the conditions of an environmental temperature of 23° C., a peel angle of 180°, and a tensile rate of 10 mm/min.

[The indentation modulus of elasticity at 25° C. of the cleaning layer is preferably from 0.1 GPa to 2 GPa, more preferably from 0.2 GPa to 1.5 GPa, still more preferably from 0.5 GPa to 1.0 GPa. When the indentation modulus of elasticity at 25° C. falls within such ranges, organic contamination resulting from the cleaning layer can be reduced. The indentation modulus of elasticity of the cleaning layer may be measured with a nanoindenter (indenter: Berkovich (triangular pyramid-shaped)) at a frequency of 100 Hz, an indentation depth of 100 nm, a measurement sample size of 1.0 cm×1.0 cm, and an amplitude of 2 nm.

The storage modulus of elasticity at 25° C. of the cleaning layer may be from 100 MPa to 2, 500 MPa, from 100 MPa to 2,000 MPa, from 100 MPa to 1,500 MPa, or from 100 MPa to 1,000 MPa. The storage modulus of elasticity is preferably from 100 MPa to 1,000 MPa. When the storage modulus of elasticity falls within the above-mentioned ranges, a cleaning sheet significantly excellent in foreign particle-removing performance can be obtained. The storage modulus of elasticity may be measured for a test piece having a length of 30 mm (measurement length) and a width of 10 mm with a solid viscoelasticity-measuring apparatus (e.g., model: RSAG-2, manufactured by TA Instruments Japan Inc.) under the conditions of a frequency of 1 Hz, a temperature increase rate of 10° C./min, and a chuck-to-chuck distance of 10 mm.

The cleaning layer has a number of residues of the cleaning layer with respect to the mirror surface of the dummy wafer of preferably 15/25 or more, more preferably 18/25 or more, still more preferably 20/25 or more, particularly preferably 23/25 or more, most preferably 25/25 or more, which is determined by a cross-cut method. When the number of residues of the cleaning layer with respect to the mirror surface of the dummy wafer, which is determined by the cross-cut method, of the cleaning layer falls within the above-mentioned ranges, for example, the adhesiveness between the cleaning layer and the transfer member such as the dummy wafer becomes even higher, and hence the cleaning layer more hardly peels from the transfer member such as the dummy wafer during cleaning.

The number of residues of the cleaning layer with respect to the mirror surface of the dummy wafer, which is determined by the cross-cut method, of the cleaning layer may be measured as described below. For example, six parallel cuts with respect to a substrate are made on a test surface with a box-cutter at intervals of 2 mm, and six parallel cuts are further made at intervals of 2 mm in the same manner so as to be perpendicular to the cuts to form a grid of 25 squares. A tape having an adhesion of 16 N/20 mm (e.g., “BT-315ST” manufactured by Nitto Denko Corporation) is strongly pressed onto the grid portion. An end of the tape is rapidly peeled at an angle of 45°, and the state of the grid is evaluated by being compared to a reference chart.

The cleaning layer contains a polyimide-based resin. When the cleaning sheet includes the cleaning layer containing the polyimide-based resin, a cleaning sheet excellent in foreign particle-removing performance and transfer performance can be obtained. The content ratio of the polyimide-based resin in the cleaning layer is preferably from 50 parts by weight to 100 parts by weight, more preferably from 70 parts by weight to 100 parts by weight, still more preferably from 90 parts by weight to 100 parts by weight, particularly preferably from 95 parts by weight to 100 parts by weight, most preferably from 98 parts by weight to 100 parts by weight with respect to 100 parts by weight of the cleaning layer. The polyimide-based resin preferably has a soft segment. The soft segment is a segment that can impart flexibility to a polymer, and may be, for example, a segment having a long-chain linear group or a long-chain branched group in a main chain, and is soft and has stretchability.

The polyimide-based resin is typically obtained by imidizing a polyamic acid. The polyamic acid may be obtained by using a tetracarboxylic dianhydride component and a diamine component as monomer components to perform a reaction in any appropriate organic solvent. In at least one embodiment of the present invention, those components are subjected to a reaction at a substantially equimolar ratio. With such configuration, the amount of a reaction residue can be reduced. As a result, a cleaning sheet particularly excellent in cleanliness can be obtained.

Examples of the tetracarboxylic dianhydride component include 3,3′,4,4′-biphenyltetracarboxylic dianhydride, 2,2′,3,3′-biphenyltetracarboxylic dianhydride, 3,3′,4,4‘-benzophenonetetracarboxylic dianhydride, 2,2’, 3,3′-benzophenonetetracarboxylic dianhydride, 4,4′-oxydiphthalic dianhydride, 2,2-bis(2,3-dicarboxyphenyl) hexafluoropropane dianhydride, 2,2-bis(3,4-dicarboxyphenyl) hexafluoropropane dianhydride (6FDA), bis(2,3-dicarboxyphenyl) methane dianhydride, bis(3,4-dicarboxyphenyl)methane dianhydride, bis(2,3-dicarboxyphenyl)sulfone dianhydride, bis(3,4-dicarboxyphenyl)sulfone dianhydride, pyromellitic dianhydride, and ethylene glycol bistrimellitic dianhydride. Those components may be used alone or in combination thereof.

Examples of the diamine component include a diamine compound that has at least two terminals each having an amine structure and has a polyether structure (hereinafter also referred to as “PE diamine compound”), an aliphatic diamine, and an aromatic diamine. Of those, a PE diamine compound may be preferably used. A dimer diamine may be used as the diamine compound.

Any appropriate compound may be adopted as the PE diamine compound. Examples of the PE diamine compound include a terminal diamine having a polypropylene glycol structure, a terminal diamine having a polyethylene glycol structure, a terminal diamine having a polytetramethylene glycol structure, and a terminal diamine having a plurality of those structures. A more specific example of the PE diamine compound is a PE diamine compound having at least two terminals each having an amine structure prepared from ethylene oxide, propylene oxide, polytetramethylene glycol, polyamine, or a mixture thereof. A structural unit derived from the PE diamine compound may serve as the soft segment in the polyimide-based resin.

The content ratio of the PE diamine compound in the monomer component for forming the polyamic acid is preferably from 10 parts by weight to 60 parts by weight, more preferably from 12 parts by weight to 50 parts by weight, still more preferably from 15 parts by weight to 45 parts by weight, particularly preferably from 20 parts by weight to 40 parts by weight with respect to 100 parts by weight of the monomer component. When the content ratio falls within such ranges, a cleaning sheet particularly excellent in foreign particle-removing performance can be obtained. In addition, a composition for forming a cleaning layer that can be easily formed into a varnish can be obtained.

The content ratio of the PE diamine compound in the diamine component for forming the polyamic acid is preferably from 20 parts by weight to 80 parts by weight, more preferably from 25 parts by weight to 75 parts by weight, still more preferably from 30 parts by weight to 70 parts by weight with respect to 100 parts by weight of the diamine component. When the content ratio falls within such ranges, a cleaning sheet particularly excellent in foreign particle-removing performance can be obtained. In addition, a composition for forming a cleaning layer that can be easily formed into a varnish can be obtained.

Examples of the aliphatic diamine include ethylenediamine, hexamethylenediamine, 1,8-, 1,10-diaminodecane, 1,12-diaminododecane, 4,9-dioxa-1,12-diaminododecane, and 1,3-bis(3-aminopropyl)-1,1,3,3-tetramethyldisiloxane (α,ω-bisaminopropyltetramethyldisiloxane). The aliphatic diamine has a molecular weight of preferably from 50 to 1,000,000, more preferably from 100 to 30,000.

Examples of the aromatic diamine include 4,4′-diaminodiphenyl ether, 3,4′-diaminodiphenyl ether, 3,3′-diaminodiphenyl ether, m-phenylenediamine, p-phenylenediamine, 4,4′-diaminodiphenylpropane, 3,3′-diaminodiphenylmethane, 4,4′-diaminodiphenyl sulfide, 3,3′-diaminodiphenyl sulfide, 4,4′-diaminodiphenyl sulfone, 3,3′-diaminodiphenyl sulfone, 1,4-bis(4-aminophenoxy)benzene, 1,3-bis(4-aminophenoxy)benzene, 1,3-bis(3-aminophenoxy)benzene, 1,3-bis(4-aminophenoxy)-2,2-dimethylpropane, and 4,4′-diaminobenzophenone.

Examples of the organic solvent (reaction solvent) to be used in the reaction between the tetracarboxylic dianhydride component and the diamine component include N, N-dimethylacetamide, N-methyl-2-pyrrolidone, and N, N-dimethylformamide. A non-polar solvent (e.g., toluene or xylene) may be used in combination therewith for adjusting the solubility of the raw material or the like.

The temperature of the reaction between the tetracarboxylic dianhydride component and the diamine component is preferably 20° C. or more, more preferably from 20° C. to 100° C.

The imidization of the polyamic acid is typically performed by heat treatment under an inert atmosphere (typically a vacuum or nitrogen atmosphere). The temperature of the heat treatment is preferably 150° C. or more, more preferably from 180° C. to 450° C.

The glass transition temperature (Tg) of the polyimide-based resin is preferably from 200° C. to 300° C., more preferably from 250° C. to 300° C., still more preferably from 250° C. to 285° C. When the glass transition temperature (Tg) falls within such ranges, the effects of the invention of the present application become significant. The glass transition temperature (Tg) is measured with a thermomechanical analyzer (TMA).

Any appropriate other component may be incorporated into the cleaning layer to the extent that the effects of the present invention are not impaired. Examples of such other component include a heat-resistant resin, a surfactant, a plasticizer, an antioxidant, a conductivity-imparting agent, a UV absorber, and a photostabilizer.

### A-3. Support

The cleaning sheet may include a support. The support may be a single layer or a multilayered body.

Any appropriate thickness may be adopted as the thickness of the support to the extent that the effects of the present invention are not impaired. Such thickness is preferably 500 μm or less, more preferably from 1 μm to 400 μm, still more preferably from 1 μm to 300 μm, particularly preferably from 1 μm to 200 μm, most preferably from 1 μm to 100 μm.

Any appropriate material may be adopted as a material for forming the support to the extent that the effects of the present invention are not impaired. Examples of the support include films made of plastic, engineering plastic, and super engineering plastic. Specific examples of the plastic, the engineering plastic, and the super engineering plastic include polyimide, polyethylene, polyethylene terephthalate, acetyl cellulose, polycarbonate, polypropylene, and polyamide.

Various physical properties such as a molecular weight of the material for the support may be appropriately selected in accordance with purposes.

A method of forming the support may be appropriately selected in accordance with purposes.

The surface of the support may be subjected to conventional surface treatment, for example, chemical or physical treatment, such as chromic acid treatment, ozone exposure, flame exposure, high-pressure shock exposure, or ionized radiation treatment, or coating treatment with an undercoating agent, in order to enhance its adhesiveness with respect to an adjacent layer, retention property, and the like.

The peel strength of the cleaning layer with respect to the support at 23° C. is, for example, 3 N/10 mm or more, preferably 3.5 N/10 mm or more, more preferably 5 N/10 mm or more. The peel strength of the cleaning layer with respect to the support at 23° C. is preferably as high as possible, but the upper limit thereof is, for example, 50 N/10 mm. A measurement method for the peel strength is in conformity with the measurement method for the “180° Peeling Adhesion B.”

### A-4. Pressure-Sensitive Adhesive Layer

The cleaning sheet may include a pressure-sensitive adhesive layer. Any appropriate material may be adopted as a material for forming such pressure-sensitive adhesive layer to the extent that the effects of the present invention are not impaired. Examples of the material for the pressure-sensitive adhesive layer include an acrylic pressure-sensitive adhesive, a silicone-based pressure-sensitive adhesive, a rubber-based pressure-sensitive adhesive, and a urethane-based pressure-sensitive adhesive.

The pressure-sensitive adhesive layer is arranged for, for example, bonding the cleaning sheet to the mirror surface of a dummy wafer. Thus, the cleaning sheet is bonded to the dummy wafer serving as a transfer member, and hence a transfer member provided with a cleaning function according to at least one embodiment of the present invention can be obtained.

The pressure-sensitive adhesive layer has a 180° peeling adhesion C with respect to the mirror surface of a dummy wafer of preferably 10 N/10 mm or more, more preferably 15 N/10 mm or more, still more preferably 20 N/10 mm or more, particularly preferably 25 N/10 mm or more, most preferably 30 N/10 mm or more, which is defined by JIS-Z-0237. When the 180° peeling adhesion C of the pressure-sensitive adhesive layer with respect to the mirror surface of the dummy wafer, which is defined by JIS-Z-0237, falls within the above-mentioned ranges, for example, adhesive strength between the pressure-sensitive adhesive layer and the dummy wafer becomes higher, and hence the cleaning sheet hardly peels from the dummy wafer during cleaning.

The thickness of the pressure-sensitive adhesive layer is preferably from 1 μm to 200 μm, more preferably from 2 μm to 100 μm, still more preferably from 3 μm to 80 μm, particularly preferably from 4 μm to 60 μm, most preferably from 5 μm to 50 μm.

### A-5. Protective Film

The cleaning sheet according to at least one embodiment of the present invention may include a protective film for protecting, for example, the cleaning layer, the support, or the pressure-sensitive adhesive layer. The protective film may be peeled in an appropriate stage.

Any appropriate material may be adopted as a material for forming the protective film to the extent that the effects of the present invention are not impaired. Examples of the material for the protective film include polyolefins, such as polyethylene, polypropylene, polybutene, polybutadiene, and polymethylpentene, polyvinyl chloride, a vinyl chloride copolymer, polyethylene terephthalate, polybutylene terephthalate, polyurethane, an ethylene vinyl acetate copolymer, an ionomer resin, an ethylene-(meth)acrylic acid copolymer, an ethylene-(meth)acrylic acid ester copolymer, polystyrene, polycarbonate, polyimide, and a fluororesin.

The protective film may be subjected to any appropriate peeling treatment to the extent that the effects of the present invention are not impaired. The peeling treatment is typically performed with a peeling agent. Examples of the peeling agent may include a silicone-based peeling agent, a long-chain alkyl-based peeling agent, a fluorine-based peeling agent, a fatty acid amide-based peeling agent, and a silica-based peeling agent.

The protective film preferably has a thickness of from 1 μm to 100 μm.

A method of forming the protective film is appropriately selected in accordance with purposes, and the film may be formed by, for example, an injection molding method, an extrusion molding method, or a blow molding method.

### B. Method of Producing Cleaning Sheet

Any appropriate production method may be adopted as a method of producing a cleaning sheet according to at least one embodiment of the present invention to the extent that the effects of the present invention are not impaired. An example of such production method is a method including: casting a composition (varnish) for forming a cleaning layer containing the polyamic acid onto a support; uniformly forming the composition into a film with a spin coater or the like; and then heating the film to directly form the cleaning layer on the support. A preferred example thereof is a method of producing a cleaning sheet according to at least one embodiment of the present invention, the method including: applying the composition (varnish) for forming a cleaning layer onto the support with the spin coater to form a film; and leaving the film at rest as required, and heating and/or drying the film as required to form a cleaning layer on the support. The composition (varnish) for forming a cleaning layer may be prepared by mechanical synthesis or synthesis involving manual intervention. The composition (varnish) for forming a cleaning layer is preferably prepared under a clean environment, and is preferably prepared by, for example, mechanical synthesis. In addition, even when the manual intervention is involved, it is preferred to adopt an operation with high cleanliness such as adjustment by an operation involving loading a raw material into a flask and stirring (e.g., stirring with a stirring blade).

In at least one embodiment of the present invention, the method of producing a cleaning sheet includes measuring a Na concentration or a Ca concentration in the composition (varnish) for forming a cleaning layer. In at least one embodiment of the present invention, when the Na concentration or the Ca concentration in the composition (varnish) for forming a cleaning layer is measured, an error (e.g., manual intervention) at the time of the adjustment of the varnish can be detected simply and with high accuracy. As a result, a cleaning layer in which metal contamination is prevented can be formed.

In at least one embodiment of the present invention, the Na concentration in the composition (varnish) for forming a cleaning layer is 10 ppm or less, preferably 8 ppm or less, more preferably 6 ppm or less. When the Na concentration falls within such ranges, a cleaning sheet excellent in cleanliness that can prevent contamination derived from the cleaning layer can be obtained. The Na concentration in the composition (varnish) for forming a cleaning layer is preferably as low as possible, and the lower limit thereof is, for example, 1 ppm (preferably 0 ppm). A composition (varnish) for forming a cleaning layer having a low Na concentration and a low Ca concentration to be described later may be obtained by, for example, preparation under a clean environment as described above. In addition, the composition (varnish) for forming a cleaning layer may be prepared in a class 1 to class 10 (ISO 14644-1) clean room. The Na concentration and the Ca concentration to be described later in the composition (varnish) for forming a cleaning layer may be measured by ion chromatography. Specifically, the Na concentration and the Ca concentration may be measured with a predetermined atomic absorption spectrophotometer (e.g., “AA-7000” manufactured by Shimadzu Corporation) based on calibration curves prepared with standard solutions for the respective measurement objects.

In at least one embodiment of the present invention, the Ca concentration in the composition (varnish) for forming a cleaning layer is 10 ppm or less, preferably 8 ppm or less, more preferably 6 ppm or less. When the Ca concentration falls within such ranges, a cleaning sheet excellent in cleanliness that can prevent contamination derived from the cleaning layer can be obtained. The Ca concentration in the composition (varnish) for forming a cleaning layer is preferably as low as possible, and the lower limit thereof is, for example, 1 ppm (preferably 0 ppm).

In at least one embodiment of the present invention, the Na concentration and the Ca concentration in the composition (varnish) for forming a cleaning layer are each preferably 10 ppm or less, more preferably 8 ppm or less, still more preferably 6 ppm or less.

The viscosity of the composition (varnish) for forming a cleaning layer is preferably from 100 mPa·s to 4,000 mPa·s, more preferably from 300 mPa·s to 3,000 mPa·s, still more preferably from 500 mPa·s to 2,000 mPa·s.

A rotational speed at the time of the formation of the film by the application of the composition (varnish) for forming a cleaning layer with the spin coater is preferably 400 rpm or more, more preferably 600 rpm or more, still more preferably 800 rpm or more. The upper limit of the rotational speed is preferably 3,000 rpm or less because the effects of the present invention can be further expressed.

A spin time at the time of the formation of the film by the application of the composition (varnish) for forming a cleaning layer with the spin coater is preferably from 5 seconds to 200 seconds, more preferably from 10 seconds to 150 seconds, still more preferably from 20 seconds to 60 seconds.

In the method of producing a cleaning sheet according to at least one embodiment of the present invention, when the composition (varnish) for forming a cleaning layer is applied to the support to form the film, and then the film is left at rest, the varnish can be further smoothed. The time period for which the film is left at rest is preferably from 5 seconds to 1,000 seconds, more preferably from 30 seconds to 600 seconds, still more preferably from 100 seconds to 400 seconds.

In the method of producing a cleaning sheet according to at least one embodiment of the present invention, after the composition (varnish) for forming a cleaning layer has been applied to form the film, the film may be heated and/or dried. The temperature at which the heating or the drying is performed is preferably from 50° C. to 200° C., more preferably from 80° C. to 150° C. The time period for which the heating or the drying is performed is preferably from 100 seconds to 900 seconds, more preferably from 300 seconds to 900 seconds, still more preferably from 600 seconds to 900 seconds.

In the method of producing the cleaning sheet according to at least one embodiment of the present invention, after the composition (varnish) for forming a cleaning layer has been applied to form a film, and the film has been heated or dried, the film may be cured under a vacuum or nitrogen atmosphere. The temperature of the curing is preferably from 200° C. to 400° C., more preferably from 250° C. to 350° C. The time period for which the heating or the drying is performed is preferably from 30 minutes to 300 minutes, more preferably from 60 minutes to 200 minutes. A cleaning resin is softened by being heated to a temperature equal to or higher than the glass transition temperature in the curing process. Thus, followability to a wafer surface is improved, and an adhesive strength between the wafer and the cleaning layer is improved.

### C. Transfer Member Provided with Cleaning Function

A transfer member provided with a cleaning function according to at least one embodiment of the present invention includes the above-mentioned cleaning sheet and a transfer member.

FIG. 4 is a schematic cross-sectional view for illustrating the transfer member provided with a cleaning function according to at least one embodiment of the present invention. In FIG. 4, a transfer member 300 provided with a cleaning function includes the cleaning sheet 100 and a transfer member 200. When the cleaning sheet 100 includes a pressure-sensitive adhesive layer, the outermost layer of the cleaning sheet 100 on the transfer member 200 side is preferably the pressure-sensitive adhesive layer.

Any appropriate transfer member may be adopted as the transfer member to the extent that the effects of the present invention are not impaired. Examples of such transfer member include: a semiconductor wafer (e.g., a silicon wafer); a substrate for a flat panel display, such as an LCD or a PDP; a compact disc; and an MR head. Of those transfer members, a semiconductor wafer (e.g., a silicon wafer) is typically given as an example of the transfer member when the transfer member is intended to clean a device for transferring a wafer in a substrate processing apparatus.

### EXAMPLES

The present invention is more specifically described below by way of Examples and Comparative Examples. However, the present invention is by no means limited thereto. In the following description, the terms “part(s)” and “%” are by weight unless otherwise stated.

### [Example 1] (Production of Varnish of Polyimide)

A varnish of 41 polyimide was produced by mechanical synthesis. Specifically, 57.0 g of 4,4′-diaminodiphenyl ether, 92 g of H₂N—CH(CH₃)—(O—CH—CH(CH₃))ₙ—NH₂ (product name: “Baxxodur EC 303”, manufactured by BASF SE, molecular weight: 2,000, n=about 33), and 1,000 g of dimethylacetamide were loaded into a separable flask mounted with a stirring device, and the mixture was stirred at room temperature until 4,4′-diaminodiphenyl ether EC 303 was completely dissolved. After that, 72.0 g of pyromellitic anhydride was slowly added to the flask over 10 minutes, and the mixture was stirred at room temperature for 1 hour. The mixture was warmed to 70° C. and stirred for 4 hours to provide a varnish (1) of polyimide. The resultant varnish (1) of polyimide had a viscosity of 1,500 mPa·s.

(Production and Evaluation of Transfer Member Provided with Cleaning Function Including Cleaning Layer)

The resultant varnish (1) of polyimide was applied onto the mirror surface of a 12-inch silicon wafer with a spin coater (manufactured by Tokyo Electron Limited, ACT-12, rotational speed=1,000 rpm, spin time=30 seconds), and was left at rest for 300 seconds. After that, the varnish was heated at 100° C. for 2 minutes so that N-methyl-2-pyrrolidone was removed. After that, the residue was heated under a vacuum at 280° C. for 2 hours. Thus, a transfer member provided with a cleaning function including a cleaning layer having a thickness of 7.0 μm was obtained. The transfer member provided with a cleaning function includes a cleaning sheet formed of the cleaning layer and the silicon wafer serving as a transfer member.

The resultant transfer member provided with a cleaning function was subjected to the following evaluations. The results are shown in Table 1.

### <Evaluations>

### Amount of Metal Transferred to Silicon Wafer

A silicon wafer (in the measurement of a surface metal amount by a total reflection X-ray fluorescence analysis method, the amount of Ti, Cr, Mn, Ni, Fe, Co, Cu, or Zn was 1×10¹⁰ atoms/cm² or less) was bonded to the cleaning layer surface of the resultant cleaning sheet (bonding conditions: one reciprocation of a 3 kg hand roller). After that, the silicon wafer was peeled, and the amount of the metal transferred to the surface bonded to the cleaning layer was measured by the total reflection X-ray fluorescence analysis method. Ti, Cr, Mn, Ni, Fe, Co, Cu, and Zn serving as measurement objects were measured under the following conditions.

As shown in Table 1, all of the atoms were equal to or less than the detection limit.
Apparatus: TREX 630III manufactured by Technos Co., Ltd.
X-ray source: W-sealed tube type X-ray source, 40 kV, 40 mA
Measurement time: 500 sec

### Na Content and Ca Content in Cleaning Layer

100 Milligrams of the cleaning layer was collected in a Teflon (trademark) container. An acid was added to the container, and the container was tightly sealed. The container was irradiated with a microwave, and pressurized acid decomposition was performed at 220° C. After that, ultrapure water was added to the container to adjust the volume to 20 ml. A Na content and a Ca content in the cleaning layer were measured by ICP-MS under the following conditions.
Decomposition apparatus: MARS 5 manufactured by CEM Corporation
Measurement apparatus: 8800 manufactured by Agilent Technologies

### Indentation Modulus of Elasticity of Cleaning Layer

The indentation modulus of elasticity of the cleaning layer was measured with a nanoindenter under the conditions of a frequency of 100 Hz, an indentation depth of 100 nm, a measurement sample size of 1.0 cm×1.0 cm, and an amplitude of 2 nm.

### (Measurement Apparatus and Measurement Conditions)

Apparatus: Tribo Indenter manufactured by Hysitron Inc.
Indenter used: Berkovich (triangular pyramid-shaped)
Measurement method: single indentation measurement
Indentation depth setting: 100 nm
Frequency: 100 Hz
Amplitude: 2 nm
Measurement atmosphere: nitrogen atmosphere
Sample size: 1 cm×1 cm

### Cleaning Property

The mirror surface of a 6-inch silicon wafer was left in the atmosphere for 6 hours to prepare a contaminated 6-inch silicon wafer. The number of foreign particles on the mirror surface was measured (Count 1). Next, the mirror surface of the contaminated 6-inch silicon wafer was bonded to the cleaning sheet, and then the cleaning sheet was peeled. The number of foreign particles on the mirror surface of the silicon wafer after the peeling was measured (Count 2). A dust-removing property was calculated by the following equation.

Dust-removing property(%)=[(Count 1−Count 2)/Count 1]×100

A cleaning property was evaluated based on the dust-removing property under the following criteria.
⊚ (Excellent): The dust-removing property was 70% or more.
◯ (Satisfactory): The dust-removing property was 50% or more and less than 70%.
Δ (Acceptable): The dust-removing property was 20% or more and less than 50%.
x (Unacceptable): The cleaning layer adhered to the mirror surface or the dust-removing property was less than 20%.

TABLE 1

| | | Example 1 |
|---|---|---|
| Amount of metal transferred to | Ti | <1.3 |
| silicon wafer (×10¹⁰ atoms/cm²) | Cr | <0.72 |
| | Mn | <0.57 |
| | Ni | <0.45 |
| | Fe | <0.35 |
| | Co | <0.30 |
| | Cu | <0.24 |
| | Zn | <0.24 |
| Na content and Ca content | Na | 0.000 |
| in cleaning layer (ppm) | Ca | 0.088 |

| | |
|---|---|
| Indentation modulus of elasticity of | 800 |
| cleaning layer (MPa) | |
| Cleaning property | ⊚ |

The cleaning sheet and the transfer member provided with a cleaning function according to at least one embodiment of the present invention are each suitably used in the cleaning of various kinds of substrate processing apparatus, such as production apparatus and inspection apparatus.

What is claimed is:

1. A cleaning sheet, comprising a cleaning layer,
wherein the cleaning layer contains a polyimide-based resin, and
wherein the cleaning layer has an amount of a metal transferred to a silicon wafer of 1×10¹¹ atoms/cm² or less, which is measured by a total reflection X-ray fluorescence analysis method.

2. The cleaning sheet according to claim 1, wherein the cleaning layer has an amount of Ca transferred to the silicon wafer of 1×10¹¹ atoms/cm² or less, which is measured by the total reflection X-ray fluorescence analysis method.

3. The cleaning sheet according to claim 1, wherein a metal content in the cleaning layer is 10 ppm or less.

4. The cleaning sheet according to claim 1, wherein a Na content and a Ca content in the cleaning layer are each 10 ppm or less.

5. The cleaning sheet according to claim 1, wherein the cleaning layer has an indentation modulus of elasticity at 25° C. of from 0.1 GPa to 2 GPa.

6. The cleaning sheet according to claim 1, further comprising a support arranged adjacent to the cleaning layer.

7. A transfer member provided with a cleaning function, comprising:
the cleaning sheet of claim 1; and
a transfer member.

8. A method of producing a cleaning sheet, comprising applying a composition for forming a cleaning layer to a support,
wherein a Na concentration and a Ca concentration in the composition for forming a cleaning layer are each 10 ppm or less.

9. The method of producing a cleaning sheet according to claim 8, further comprising measuring one of the Na concentration or the Ca concentration in the composition for forming a cleaning layer.
